(19) United States
(12) Patent Application Publication
(10) Pub. No.: US 2023/0157064 A1
(43) Pub. Date: May 18, 2023

(54) OLED DISPLAY PANEL, MANUFACTURING METHOD THEREOF, AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Zhitao Zhu, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/963,498

(22) PCT Filed: Jun. 15, 2020
(86) PCT No.: PCT/CN2020/096157

§ 371 Date: Jul. 20, 2020

(30) Foreign Application Priority Data
Apr. 27, 2020 (CN) 202010342216.1

(51) Int. Cl. H10K 50/80; H10K 71/00

(52) U.S. Cl. CPC H10K 50/868; H10K 71/00

(57) ABSTRACT

An organic light emitting diode (OLED) display panel, a manufacturing method thereof, and a display device are provided. The OLED display panel includes a first backplane, a fixing member, a second backplane, a display panel, and a flexible polarizer. The flexible polarizer and the display panel extend from a side of the first backplane away from the fixing member and are bent to a side of the second backplane away from the fixing member. There is a gap without filler between the display panel and the fixing member.

### FIELD OF INVENTION

The present application relates to the field of display technologies, and more particularly to an organic light emitting diode (OLED) display panel, a manufacturing method thereof, and a display device.

### BACKGROUND OF INVENTION

With wide applications of organic light emitting diode (OLED) technologies in the display panel industry, the biggest advantage of OLED products is their flexible and foldable characteristics.

At present, pad bending technologies of display panel are made into a large R arc shape, and a bending radius R ranges between 3 mm and 5 mm, which cannot increase a screen ratio of a display.

After a display panel is processed with a laser lift off (LLO) process, a pad bending area relies on MLC dispensing to protect itself. Generally, a thickness of a glue in the pad bending area generally ranges between 50 μm and 80 μm. However, after a liquid glue is cured, there will be uneven thickness, resulting in a gap between a colloid and a film layer, thereby causing various display-type defects in the display panel after being bent. Specifically, when a thickness of the colloid is uneven, a shape of pad bending is easily affected. For example, when the colloid in a bending area is too thick, the colloid interferes with other components in the bending area and may even cause wave warpage in the bending area.

Dispensing process is in an entire pad bending area. A location of a touch panel flexible print circuit (TP FPC) is to cross a dispensing area. At this location, flatness of dispensing will cause unevenness of a surface of a touch panel. The uneven dispensing affects a customer's visual experience of DF products (full flexible dynamic bending products) and affects a performance of the display panel.

In addition, during a transportation process, due to an uneven thickness of the colloid in the bending area, a wiring of an array substrate is not completely fixed, and it is easy to be pulled, resulting in damage to the wiring of the array substrate.

### SUMMARY OF INVENTION

An object of the present invention is to provide an organic light emitting diode (OLED) display panel, a manufacturing method thereof, and a display device, to solve a technical problem that a thickness of a colloid is not uniform after dispensing a current OLED display panel, which affects a shape of pad bending, interference and wave warping are likely to occur, and a circuit of an array substrate is prone to disconnection.

In order to achieve the above object, an embodiment of the present invention provides an organic light emitting diode (OLED) display panel comprising a first backplane, a fixing member, a second backplane, a display panel, and a flexible polarizer. The fixing member is fixed to a side of a surface of the first backplane. The second backplane is fixed to a side of the fixing member away from the first backplane. The display panel is disposed on a surface of the first backplane away from the fixing member. The flexible polarizer is disposed on a surface of the display panel away from the fixing member. The flexible polarizer and the display panel extend from a side of the first backplane away from the fixing member and bend to a side of the second backplane away from the fixing member, and there is a gap without filler between the display panel and the fixing member.

Further, on the side of the fixing member away from the first backplane, the flexible polarizer partially covers the display panel, so that a side of the display panel is exposed.

Further, a bending radius of the flexible polarizer ranges between 0.2 mm and 0.6 mm.

Further, a thickness of the flexible polarizer ranges between 43 μm and 80 μm.

Further, a modulus of the flexible polarizer ranges between 2500 MPA and 3500 MPA.

Further, the OLED display panel further comprises an optical adhesive layer disposed on a side surface of the flexible polarizer away from the first backplane and a cover plate covering a side surface of the optical adhesive layer away from the first backplane.

Further, edges of the second backplane and the fixing member are aligned with each other.

In order to achieve the above object, an embodiment of the present invention further provides a method of manufacturing an OLED display panel comprising the following steps: providing a first backplane and a second backplane, installing the first backplane on an upper surface of a fixing member, wherein the fixing member is fixed to a side of a surface of the first backplane, setting a display panel on upper surfaces of the first backplane and the second backplane, attaching a flexible polarizer to an upper surface of the display panel, and bending the display panel and the flexible polarizer, wherein the flexible polarizer and the display panel are extended from the upper surface of the first backplane and bent to a lower surface of the second backplane, and there is a gap without filler between the flexible display assembly and the fixing member.

Further, in a step of bending the display panel and the flexible polarizer, the edges of the second backplane and the fixing member are aligned with each other, and on the lower surface of the fixing member, the flexible polarizer partially covers the display panel, so that a side of the display panel is exposed.

In order to achieve the above object, an embodiment of the present invention further provides a display device comprising the above OLED display panel.

Beneficial Effect:

The technical effect of an embodiment of the present invention is to provide an OLED display panel, a manufacturing method thereof, and a display device. A current MLC dispensing process has been removed. On one hand, flexibility and extensibility of a flexible polarizer can make bending of a display panel larger, effectively increasing a screen ratio of the display. On another hand, a length of the flexible polarizer is extended so that it is bent from an upper surface of a first backplane and extends to a lower surface of a second backplane. This can effectively prevent a colloid from interfering with other components in a bending area and wave warping in the bending area. This prevents damage to a wiring of an array substrate, thereby improving a performance of the OLED display panel.

### DESCRIPTION OF DRAWINGS

The technical solutions and other beneficial effects of the present application will be apparent through the detailed description of the specific implementation of the present application in conjunction with the accompanying drawings.

FIG. 1 is a schematic structural diagram of an organic light emitting diode (OLED) display panel according to an embodiment of the present invention.

FIG. 2 is a flowchart of an OLED display panel according to an embodiment of the present invention.

FIG. 3 is a schematic structural diagram of a flexible polarizer before bending according to an embodiment of the present invention.

FIG. 4 is a schematic structural diagram of a flexible polarizer after bending according to an embodiment of the present invention.

The identification of the drawings is as follows:

1 first backplane, 2 fixing member.

3 second backplane, 4 display panel.

5 flexible polarizer, 6 optical adhesive layer.

7 cover plate, 8 chip on film.

9 IC module, 10 display printed circuit board.

100 bending area, 101 first bending portion, 102 second bending portion.

### DETAILED DESCRIPTION OF PREFERRED EMBODIMENTS

The technical solutions in the embodiments of the present application will be described clearly and completely with reference to the drawings in the embodiments of the present application. Obviously, the described embodiments are only a part of the embodiments of the present application, but not all the embodiments. Based on the embodiments in the present application, all other embodiments obtained by those skilled in the art without making creative work fall within the protection scope of the present application.

In the present application, unless specified or limited otherwise, the terms “mounted,” “connected,” “coupled,” “fixed” and the like are used broadly, and may be, for example, fixed connections, detachable connections, or integral connections; may also be mechanical or electrical connections; may also be direct connections or indirect connections via intervening structures; may also be inner communications of two elements or interactions of two elements, which can be understood by those skilled in the art according to specific situations.

In the present application, unless specified or limited otherwise, a structure in which a first feature is “on” a second feature may include an embodiment in which the first feature directly contacts the second feature, and may also include an embodiment in which the first feature indirectly contacts the second feature via an intermediate medium. Moreover, a structure in which a first feature is “on”, “over” or “above” a second feature may indicate that the first feature is right above the second feature or obliquely above the second feature, or just indicate that a horizontal level of the first feature is higher than the second feature. A structure in which a first feature is “below”, or “under” a second feature may indicate that the first feature is right under the second feature or obliquely under the second feature, or just indicate that a horizontal level of the first feature is lower than the second feature.

Various embodiments and examples are provided in the following description to implement different structures of the present application. In order to simplify the present application, certain elements and settings will be described. However, these elements and settings are only examples and are not intended to limit the present application. In addition, reference numerals may be repeated in different examples in the present application. This repeating is for the purpose of simplification and clarity and does not refer to relations between different embodiments and/or settings. Furthermore, examples of different processes and materials are provided in the present application. However, it would be appreciated by those skilled in the art that other processes and/or materials may be also applied.

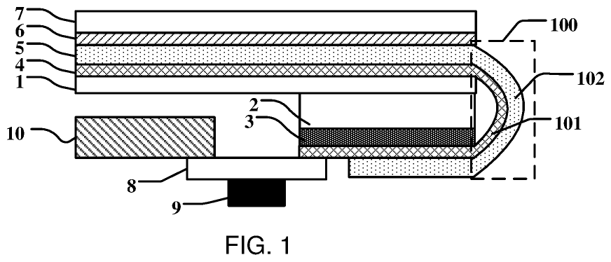

As shown in FIG. 1, an embodiment provides an organic light emitting diode (OLED) display panel including a first backplane 1, a fixing member 2, a second backplane 3, a display panel 4, a flexible polarizer 5, an optical adhesive layer 6, and a cover plate 7.

The fixing member 2 is fixed to a side of an upper surface of the first backplane 1. The second backplane 3 is fixed to a lower surface of the fixing member 2 and is aligned with edges of the fixing member 2.

In an embodiment, PET material with unique glue on both sides of the fixing member 2 (stiffener) supports the first backplane 1 and the second backplane 3, thereby fixing an entire OLED display panel.

The display panel 4 is disposed on the first backplane 1 and is bent and extended to a lower surface of the second backplane 3 to form a first bent portion 101. There is a gap without filler between the display panel 4 and the fixing member 2.

The flexible polarizer 5 has good flexibility and ductility, and its structure mainly includes a polarizer base and first and second protective layers on upper and lower surfaces of the polarizer base. Material of the polarizer base includes polyvinyl alcohol (PVA). PVA film is a high-molecular polymer, dyed with various types of dichroic organic dyes, and it is extended under certain humidity and temperature conditions to make it absorb dichroic dyes to form polarizing properties. After dehydration and drying, the polarizer base is formed. Material of the first protective layer and material of the second protective layer include triacetyl cellulose (TAC). TAC films are hydrophilic and will quickly deform, shrink, relax, decline, and have low strength in a hot and humid environment. They are brittle and easily broken, which is not conducive to use and processing. Therefore, on both sides of the polarizer base, the TAC films with high strength, high light transmittance, and humidity resistance are provided for protection.

A length of the flexible polarizer 5 is less than a length of the display panel 4. Specifically, the flexible polarizer 5 completely covers the display panel 4 corresponding to the first backplane 1 and covers the display panel 4 corresponding to part of the second backplane 3. This ensures that after bonding of the flexible polarizer 5 is completed, circuit of an array substrate in the display panel 4 can be protected, and circuit of the array substrate is prevented from being damaged.

The flexible polarizer 5 is disposed on a side surface of the display panel 4 away from the fixing member, and bends and extends with the display panel 4 below the fixing member 2 to form a second bending portion 102. The bending portion 101 forms a bending area 100 at the second bending portion 102. Modulus of the flexible polarizer 5 ranges between 2500 MPA and 3500 MPA, preferably 2800 MPA, 3000 MPA, or 3100 MPA, which has a softer and thinner effect. A bending radius of the flexible polarizer 5 ranges between 0.2 mm and 0.6 mm, which corresponds to a bending radius of the second bending portion 102 of 0.2 mm to 0.6 mm, preferably 0.3 mm, 0.45 mm, 0.48 mm, or 0.5 mm. A bending radius of a current bending area ranges between 3 mm and 5 mm. The bending radius of the bending area of this embodiment ranges between 0.2 mm and 0.6 mm, which can effectively increase a screen ratio of the display. It should be noted that the bending radius of the flexible polarizer 5 of this embodiment is the maximum radius of the bending area.

On a side of the fixing member 2 away from the first backplane 1, since the length of the flexible polarizer 5 is less than the length of the display panel 4, the flexible polarizer partially covers the display panel 4 so that a side of the display panel 4 is exposed. A thickness of the flexible polarizer 5 ranges from 43 μm to 80 μm, preferably 45 μm, 48 μm, 50 μm, 55 μm, 60 μm, 68 μm, 70 μm, 72 μm, or 78 μm, to avoid excessive stress after bending the flexible polarizer 5 and affecting the bending effect.

Compared with the prior art, an embodiment of the present application provides an OLED display panel. A current MLC dispensing process has been removed. On one hand, flexibility and extensibility of a flexible polarizer can make bending of a display panel larger, effectively increasing a screen ratio of the display. On another hand, a length of the flexible polarizer is extended so that it is bent from an upper surface of a first backplane and extends to a lower surface of a second backplane. This can effectively prevent a colloid from interfering with other components in a bending area and wave warping in the bending area. This prevents damage to a wiring of an array substrate, thereby improving a performance of the OLED display panel.

The OLED display panel further includes a chip on film 8 (COF), an IC module 9, and a display printed circuit board 10 (panel FPC). The IC module 9 is disposed on the chip on film (COF) 8. The IC module 9 is often used as a source driver and a gate driver for display driving. In a driving circuit, one end of the COF 8 is connected to the display printed circuit board 10 and is responsible for receiving data signals transmitted from the display printed circuit board 10. Another end of the COF is connected to the display panel 4, which is used to transmit the data signal output by the IC to the display panel to drive the display panel for display.

The OLED display panel further includes an optical adhesive layer 6 and a cover plate 7. The optical adhesive layer 6 is provided between the polarizer 5 and the cover plate 7 for the polarizer 5 and the cover plate 7.

An embodiment of the present application provides an OLED display panel. A current MLC dispensing process has been removed. On one hand, flexibility and extensibility of a flexible polarizer can make bending of a display panel larger, effectively increasing a screen ratio of the display. On another hand, a length of the flexible polarizer is extended so that it is bent from an upper surface of a first backplane and extends to a lower surface of a second backplane. This can effectively prevent a colloid from interfering with other components in a bending area and wave warping in the bending area. This prevents damage to a wiring of an array substrate, thereby improving a performance of the OLED display panel.

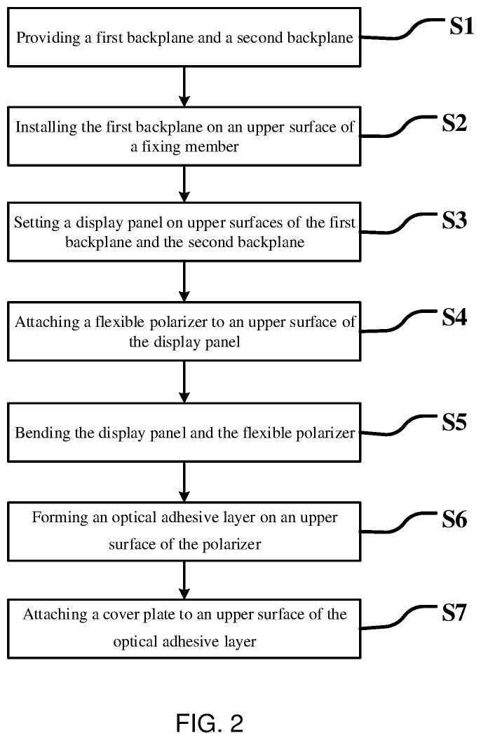

As shown in FIG. 2, an embodiment also provides a method of manufacturing an OLED display panel, including the following steps S1) to S7).

S1) providing a first backplane and a second backplane.

S2) installing the first backplane on an upper surface of a fixing member, wherein the fixing member is fixed to a side of a surface of the first backplane.

S3) setting a display panel on upper surfaces of the first backplane and the second backplane.

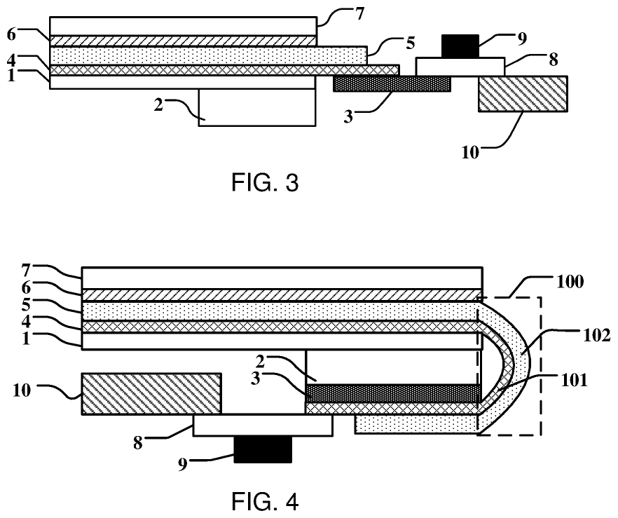

As shown in FIG. 3, the display panel 4 is disposed on the first backplane 1, an upper surface of the display panel 4 is connected to the COF 8, and an IC module 9 is disposed on the COF 8. Specifically, in a driving circuit, one end of the COF 8 is connected to the display printed circuit board 10 and is responsible for receiving data signals transmitted from the display printed circuit board 10. Another end of the COF is connected to the display panel 4, which is used to transmit the data signal output by the IC to the display panel to drive the display panel for display.

S4) attaching a flexible polarizer to an upper surface of the display panel. The flexible polarizer has good flexibility and ductility, and its structure mainly includes a polarizer base and first and second protective layers on upper and lower surfaces of the polarizer base. Material of the polarizer base includes polyvinyl alcohol (PVA). PVA film is a high-molecular polymer, dyed with various types of dichroic organic dyes, and it is extended under certain humidity and temperature conditions to make it absorb dichroic dyes to form polarizing properties. After dehydration and drying, the polarizer base is formed. Material of the first protective layer and material of the second protective layer include triacetyl cellulose (TAC). TAC films are hydrophilic and will quickly deform, shrink, relax, decline, and have low strength in a hot and humid environment. They are brittle and easily broken, which is not conducive to use and processing. Therefore, on both sides of the polarizer base, the TAC films with high strength, high light transmittance, and humidity resistance are provided for protection. Modulus of the flexible polarizer 5 ranges between 2500 MPA and 3500 MPA, preferably 2800 MPA, 3000 MPA, or 3100 MPA, which has a softer and thinner effect.

As shown in FIG. 3, a length of the flexible polarizer 5 is less than a length of the display panel 4. Specifically, the flexible polarizer 5 completely covers the display panel 4 corresponding to the first backplane 1 and covers the display panel 4 corresponding to part of the second backplane 3. This ensures that after bonding of the flexible polarizer 5 is completed, circuit of an array substrate in the display panel 4 can be protected, and circuit of the array substrate is prevented from being damaged.

S5) bending the display panel and the flexible polarizer, wherein the flexible polarizer and the display panel are extended from the upper surface of the first backplane and bent to a lower surface of the second backplane, and there is a gap without filler between the flexible display assembly and the fixing member.

As shown in FIG. 4, the display panel 4 is disposed on the first backplane 1 and is bent and extended to a lower surface of the second backplane 3 to form a first bent portion 101. There is a gap without filler between the display panel 4 and the fixing member 2.

The flexible polarizer 5 is disposed on a side surface of the display panel 4 away from the fixing member, and bends and extends with the display panel 4 below the fixing member 2 to form a second bending portion 102. The bending portion 101 forms a bending area 100 at the second bending portion 102. The bending portion 101 forms a bending area 100 at the second bending portion 102. The display panel 4 is fixed to a lower surface of the fixing member 2 and is aligned with edges of the fixing member 2. A bending radius of the flexible polarizer 5 ranges between 0.2 mm and 0.6 mm, which corresponds to a bending radius of the second bending portion 102 of 0.2 mm to 0.6 mm, preferably 0.3 mm, 0.45 mm, 0.48 mm, or 0.5 mm. A bending radius of a current bending area ranges between 3 mm and 5 mm. The bending radius of the bending area of this embodiment ranges between 0.2 mm and 0.6 mm, which can effectively increase a screen ratio of the display. It should be noted that the bending radius of the flexible polarizer 5 of this embodiment is the maximum radius of the bending area.

On a side of the fixing member 2 away from the first backplane 1, since the length of the flexible polarizer 5 is less than the length of the display panel 4, the flexible polarizer partially covers the display panel 4 so that a side of the display panel 4 is exposed. A thickness of the flexible polarizer 5 ranges from 43 μm to 80 μm, preferably 45 μm, 48 μm, 50 μm, 55 μm, 60 μm, 68 μm, 70 μm, 72 μm, or 78 μm, to avoid excessive stress after bending the flexible polarizer 5 and affecting the bending effect.

Compared with the prior art, an embodiment of the present application provides an OLED display panel. A current MLC dispensing process has been removed. On one hand, flexibility and extensibility of a flexible polarizer can make bending of a display panel larger, effectively increasing a screen ratio of the display. On another hand, a length of the flexible polarizer is extended so that it is bent from an upper surface of a first backplane and extends to a lower surface of a second backplane. This can effectively prevent a colloid from interfering with other components in a bending area and wave warping in the bending area. This prevents damage to a wiring of an array substrate, thereby improving a performance of the OLED display panel.

In an embodiment, PET material with unique glue on both sides of the fixing member (stiffener) supports the first backplane and the second backplane, thereby fixing an entire OLED display panel.

S6) forming an optical adhesive layer on an upper surface of the polarizer. An optical glue solution is coated on the upper surface of the polarizer 5 to form an optical adhesive layer 6, as shown in FIG. 4.

S7) attaching a cover plate to an upper surface of the optical adhesive layer. A cover plate 7 is attached to the upper surface of the optical adhesive layer 6, as shown in FIG. 4. The optical adhesive layer is used to bond the polarizer and the cover plate.

An embodiment of the present application provides a method of manufacturing an OLED display panel. A current MLC dispensing process has been removed. On one hand, flexibility and extensibility of a flexible polarizer can make bending of a display panel larger, effectively increasing a screen ratio of the display. On another hand, a length of the flexible polarizer is extended so that it is bent from an upper surface of a first backplane and extends to a lower surface of a second backplane. This can effectively prevent a colloid from interfering with other components in a bending area and wave warping in the bending area. This prevents damage to a wiring of an array substrate, thereby improving a performance of the OLED display panel.

An embodiment also provides a display device including the above OLED display panel. The display device may be a mobile phone, a computer, a TV, a smart wearable device, etc., which is not particularly limited in this embodiment.

In the above embodiments, the description of each embodiment has its own emphasis. For a part that is not detailed in an embodiment, you can refer to the related descriptions of other embodiments.

The OLED display panel, the manufacturing method thereof, and the display device provided by the embodiments of the present application have been described in detail above. This article uses specific examples to explain the principles and implementation of the present application. The descriptions of the above embodiments are only used to help understand the technical solutions and core ideas of the present application. Those of ordinary skill in the art should understand that they can still modify the technical solutions described in the foregoing embodiments, or equivalently replace some of the technical features. However, these modifications or substitutions do not deviate the essence of the corresponding technical solutions from the scope of the technical solutions of the embodiments of the present application.

What is claimed is:

1. An organic light emitting diode (OLED) display panel, comprising:
a first backplane;
a fixing member fixed to a side of a surface of the first backplane;
a second backplane fixed to a side of the fixing member away from the first backplane; and
a display panel disposed on a surface of the first backplane away from the fixing member;
a flexible polarizer disposed on a surface of the display panel away from the fixing member;
wherein the flexible polarizer and the display panel extend from a side of the first backplane away from the fixing member and bend to a side of the second backplane away from the fixing member, and there is a gap without filler between the display panel and the fixing member.

2. The OLED display panel according to claim 1, wherein on the side of the fixing member away from the first backplane, the flexible polarizer partially covers the display panel, so that a side of the display panel is exposed.

3. The OLED display panel according to claim 1, wherein a bending radius of the flexible polarizer ranges between 0.2 mm and 0.6 mm.

4. The OLED display panel according to claim 1, wherein a thickness of the flexible polarizer ranges between 43 μm and 80 μm.

5. The OLED display panel according to claim 1, wherein a modulus of the flexible polarizer ranges between 2500 MPA and 3500 MPA.

6. The OLED display panel according to claim 1, further comprising:
an optical adhesive layer disposed on a side surface of the flexible polarizer away from the first backplane; and
a cover plate covering a side surface of the optical adhesive layer away from the first backplane.

7. The OLED display panel according to claim 1, wherein edges of the second backplane and the fixing member are aligned with each other.

8. A method of manufacturing an OLED display panel, comprising the following steps:
providing a first backplane and a second backplane;
installing the first backplane on an upper surface of a fixing member, wherein the fixing member is fixed to a side of a surface of the first backplane;
setting a display panel on upper surfaces of the first backplane and the second backplane;
attaching a flexible polarizer to an upper surface of the display panel; and
bending the display panel and the flexible polarizer, wherein the flexible polarizer and the display panel are extended from the upper surface of the first backplane and bent to a lower surface of the second backplane, and there is a gap without filler between the flexible display assembly and the fixing member.

9. The method of manufacturing the OLED display panel according to claim 8, wherein
in a step of bending the display panel and the flexible polarizer, the edges of the second backplane and the fixing member are aligned with each other;
on the lower surface of the fixing member, the flexible polarizer partially covers the display panel, so that a side of the display panel is exposed.

10. A display device comprising the OLED display panel according to claim 1.
